(19) United States
(12) Patent Application Publication
(10) Pub. No.: US 2026/0096472 A1
(43) Pub. Date: Apr. 2, 2026

(54) EXTENDED HYBRID BONDING WITH A PHOTONIC INTERFACE

(71) Applicant: Intel Corporation, Santa Clara, CA (US)

(72) Inventors: Brandon M. RAWLINGS, Chandler, AZ (US); Adel A. ELSHERBINI, Chandler, AZ (US); Georgios C. DOGIAMIS, Chandler, AZ (US); Veronica STRONG, Hillsboro, OR (US); Feras EID, Chandler, AZ (US); Nada SEKELJIC, Hillsboro, OR (US); James E. JAUSSI, Hillsboro, OR (US); Haisheng RONG, Pleasanton, CA (US); Henning BRAUNISCH, Phoenix, AZ (US); Patricia Helena JASTRZEBSKA-PERFECT, Cambridge, MA (US)

(21) Appl. No.: 18/899,416

(22) Filed: Sep. 27, 2024

(51) Int. Cl. H01L 25/16; G02B 6/42; H01L 23/00; H01L 23/498

(52) U.S. Cl. CPC H10W 90/00; G02B 6/4245; H10W 70/635; H10W 90/701; H10W 90/794

(57) ABSTRACT

Embodiments disclosed herein include an apparatus that comprises a first layer with a first dielectric material, a second layer with a second dielectric material embedded within the first layer, where the second dielectric material has a higher index of refraction than the first dielectric material, and a first contact that is electrically conductive embedded in the first layer. In an embodiment, a third layer comprises a third dielectric material, a fourth layer comprising a fourth dielectric material and is embedded within the third layer, where the fourth dielectric material has a higher index of refraction than the third dielectric material, and a second contact that is electrically conductive embedded in the third layer. In an embodiment, the first layer directly contacts the third layer, the second layer directly contacts the fourth layer, and the first contact directly contacts the second contact.

### BACKGROUND

As bandwidth requirements within electronic systems rapidly increase over time, electrical I/O performance and scaling are struggling to keep pace. With electrical I/Os continuing to consume more power to keep up with demands, the amount of energy available for computing functions within the electronic system will be limited. In order to provide a more efficient data transfer solution, the addition of photonics systems (e.g., silicon photonic systems) to form optoelectronic systems is being investigated. For example, photonics systems may provide higher efficiency, lower latency, and higher bandwidths at a reduced power.

### BRIEF DESCRIPTION OF THE DRAWINGS

FIG. 1A is cross-sectional illustration of a device that comprises a first substrate hybrid bonded to a second substrate with a first optical waveguide directly bonded to a second optical waveguide, in accordance with an embodiment.

FIG. 1B is a cross-sectional illustration of a device that comprises a first substrate hybrid bonded to a second substrate with a first optical waveguide directly coupled to a second optical waveguide, in accordance with an additional embodiment.

FIG. 1C is a plan view illustration of overlapping optical waveguides that enable adiabatic optical coupling, in accordance with an embodiment.

FIG. 2A-2D are cross-sectional illustrations that depict a process for forming a device with hybrid bonded interfaces that include contacting optical waveguides, in accordance with an embodiment.

FIG. 3A-3C are cross-sectional illustrations that depict a process for forming a device with an embedded optical waveguide at a surface of the substrate that is able to be used for hybrid bonding, in accordance with an embodiment.

FIG. 4 is a flow diagram of a process for hybrid bonding two layers together in order to form optically coupled waveguides, in accordance with an embodiment.

FIG. 5 is a cross-sectional illustration of a portion of a device with hybrid bonded interfaces that includes optical waveguide structures that enable the formation of an optical filter and/or an optical resonator, in accordance with an embodiment.

FIG. 6A is a cross-sectional illustration of a hybrid bonded device that allows for optical coupling between substrates through the use of an optical coupling structure at the interface between substrates, in accordance with an embodiment.

FIG. 6B is a plan view illustration of the optical coupling structure of FIG. 6A, in accordance with an embodiment.

FIG. 6C is a plurality of cross-sectional segments of the optical coupling structure in FIG. 6B, in accordance with an embodiment.

FIG. 7A is a cross-sectional illustration of a device with a pair of dies hybrid bonded to an interposer to provide optical coupling between the two dies, in accordance with an embodiment.

FIG. 7B is a cross-sectional illustration of an electronic system with an interposer for optically coupling a pair of dies together, in accordance with an embodiment.

FIG. 8 is a schematic of a computing device built in accordance with an embodiment.

### EMBODIMENTS OF THE PRESENT DISCLOSURE

Described herein are optoelectronic systems that include extended hybrid bonding with a photonic interface, in accordance with various embodiments. In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

As noted above, optical interconnects within electronic packages are a viable solution in order to provide more efficient data transfer with much higher bandwidths compared to existing electrical IO architectures. One issue with optical interconnects is the requirement for high precision alignment in order to allow for the optical signals to be propagated from one device to another. For example, when two optical waveguides are optically coupled together (i.e., where an optical signal passes from a first optical waveguide into a second optical waveguide), the alignment may need to be accurate to within several microns in some applications.

The alignment between optical interconnects is difficult to control, especially when the optical interconnects are fabricated on different substrates. Alignment between different substrates is a problem of particular interest as the demand for 2.5D and 3D optoelectronic systems increases. For example, in 2.5D and/or 3D optoelectronic systems, an optical signal from a first die needs to be propagated into a second die, an interposer, or the like. Existing interconnect architectures may not provide the desired alignment tolerance to provide efficient optical coupling between the two dies.

However, advances in hybrid bonding have led to more accurate assembly of multiple dies, interposers, and/or the like. Hybrid bonding typically includes pads (or other interconnects architectures) that are provided within a dielectric layer at a surface of the substrate. The opposing substrate also has a pad within a dielectric layer at a surface of the opposing die. In such an embodiment, the two substrates are brought together so that the two pads directly contact each other to form a bond, and the two dielectric layers are brought together in order to form a bond. That is, the bond between substrates may comprise a metal-to-metal bond and a dielectric-to-dielectric bond. These metal-to-metal bonds rely on extreme precision and control of the profile of the bonding surfaces. Existing hybrid bonding architectures have shown the ability to align pads with sub-micron accuracy.

With such accuracy provided by the hybrid bonding process, embodiments disclosed herein extend the benefits of existing electrical hybrid bonding solutions in order to incorporate optical coupling as well. For example, a first optical waveguide may be fabricated into the bonding surface of a first substrate, and a second optical waveguide may be fabricated into the bonding surface of a second substrate. During the hybrid bonding, the first optical waveguide may be directly bonded to the second optical waveguide. Since the hybrid bonding process has high placement precision, the first optical waveguide is accurately coupled to the second optical waveguide (e.g., with sub-micron precision). As such, efficient optical coupling between the first substrate and the second substrate can be enabled.

In an embodiment, an optical waveguide may be fabricated within the dielectric layer of the substrate that is used as the bonding interface. In some embodiments, the bonding interface dielectric layer may have a low refractive index, and the optical waveguide may be a dielectric material that has a higher refractive index. As such, the bonding interface may function as a cladding layer for the optical waveguide. Lithography and deposition processes to form the optical waveguide may be implemented substantially in parallel with the fabrication of electrical interconnects. As such, the integration of the optical waveguides at the bonding interface may not significantly increase the complexity of the fabrication of the devices.

In some embodiments, the integrated optical waveguides proximate to the bonding interface may be used for various different applications. For example, the optical waveguides may be used to send optical signals (e.g., optical data signals) from a first substrate to a second substrate. In other embodiments, the optical waveguides may be fabricated with structures that are suitable for forming optical components such as optical resonators, optical filters, or the like. In some optical components, the optical waveguide may have a vertical portion and a horizontal portion. Such non-linear optical waveguides may be fabricated with etching and deposition processes. Curved corners for transitioning from a horizontal portion to a vertical portion may be fabricated using grayscale lithography or the like.

Embodiments disclosed herein may also include optical waveguides at the bonding interface that function as optical couplers. The optical couplers may be used in order to propagate optical signals between different layers within one or more substrates. That is, an optical signal may be propagated in a vertical direction without the need of a vertically oriented optical waveguide. As such, the integration and fabrication of optical interconnects are simplified. For example, the lack of vertically oriented optical waveguides may allow for simpler routing schemes. This may allow for more optical IO lanes to be provided within a given area (which may increase bandwidth), and/or the cost to fabricate the optical IO lanes may be reduced.

The combination of the different embodiments described herein allow for efficient 2.5D and/or 3D optoelectronic systems. For example, various different types of dies may be optically coupled to each other directly and/or through an interposer. As used herein, “optically coupled” may refer to two components that are capable of transmitting and/or receiving optical signals to/from each other. In some instances, two components may be optically coupled when an optical signal propagates from the first component directly to the second component. Other embodiments may include two optically coupled components that include an intermediary component. For example, an optical signal may be transmitted by a first component into one or more intermediary components, and one of the intermediary components propagates the optical signal to the second component. For example, a first die may be optically coupled to a second die when an optical signal is propagated from the first die to the second die along an optical waveguide that is provided on an interposer that is bonded to both the first die and the second die.

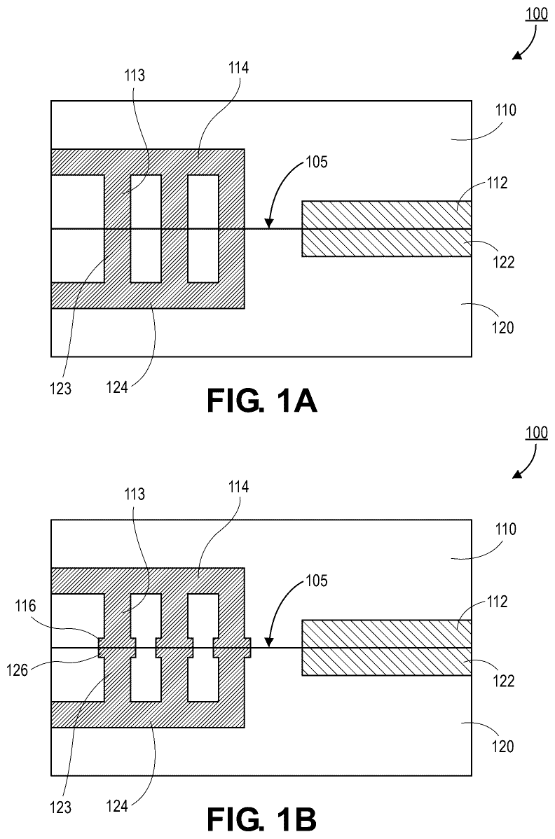

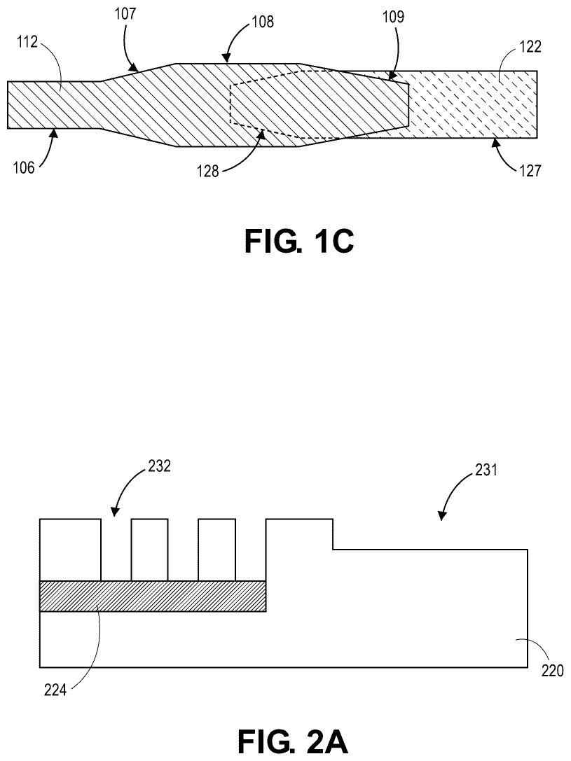

Referring now to FIG. 1A, a cross-sectional illustration of a portion of a device 100 is shown, in accordance with an embodiment. In an embodiment, the device 100 may be a hybrid bonded device 100 that includes a first substrate that is directly bonded to a second substrate. In the embodiment shown in FIG. 1A, a first dielectric layer 110 of the first substrate (top) and a second dielectric layer 120 of the second substrate (bottom) are shown. The first substrate and the second substrate may comprise any type of die, an interposer, or the like. A more detailed description of the dies and/or interposers, as well as the overall structure of the device 100 is described below.

In an embodiment, the first dielectric layer 110 and the second dielectric layer 120 may comprise any suitable dielectric material compatible with a hybrid bonding process. In a particular embodiment, the first dielectric layer 110 and the second dielectric layer 120 may comprise dielectric materials with relatively low refractive indices. For example, the first dielectric layer 110 and/or the second dielectric layer 120 may comprise silicon dioxide, glass, or the like. The use of low refractive index dielectric materials for the first dielectric layer 110 and the second dielectric layer 120 may function as the cladding layer for the first optical waveguide 112 and the second optical waveguide 122, respectively.

In an embodiment, the first dielectric layer 110 may be directly bonded to the second dielectric layer 120 along a bonding interface 105. In an embodiment, the bonding interface 105 may also include a direct bond between the first optical waveguide 112 and the second optical waveguide 122. The first optical waveguide 112 and the second optical waveguide 122 may comprise dielectric materials with relatively high refractive indices. More generally, a refractive index of the first optical waveguide 112 may be higher than a refractive index of the first dielectric layer 110, and a refractive index of the second optical waveguide 122 may be higher than a refractive index of the second dielectric layer 120. For example, the first optical waveguide 112 and/or the second optical waveguide 122 may comprise a silicon nitride, a silicon oxynitride, a silicon carbon nitride, a doped silicon oxide, a polymer material (e.g. polyimide), an epoxy based material, or the like. In some embodiments, the first optical waveguide 112 and the second optical waveguide 122 may comprise an inorganic-to-inorganic dielectric bond, an organic-to-inorganic dielectric bond, and/or an organic-to-organic dielectric bond.

In some embodiments, the first optical waveguide 112 and the second optical waveguide 122 may be referred to as a single optical waveguide structure. For example, the bonding process may result in there being no discernable boundary between the first optical waveguide 112 and the second optical waveguide 122. In such an embodiment, the combined optical waveguide (which may sometimes be referred to as an interface optical waveguide herein) may be partially embedded in the first dielectric layer 110 and the second dielectric layer 120. In such an embodiment, the bonding interface 105 between the first dielectric layer 110 and the second dielectric layer 120 may be positioned between a top surface of the interface optical waveguide and a bottom surface of the interface optical waveguide.

In an embodiment, the first optical waveguide 112 may be optically coupled to the second optical waveguide 122. That is, an optical signal that passes through the first optical waveguide 112 may be able to be propagated into the second optical waveguide 122 and/or an optical signal that passes through the second optical waveguide 122 may be able to be propagated into the first optical waveguide 112. In the illustrated embodiment, the first optical waveguide 112 is perfectly aligned with the second optical waveguide 122. Though, some amount of misalignment may be present in some embodiments. However, the use of a hybrid bonding operation may allow for the misalignment to be approximately one micron or less, or approximately 0.5 microns or less, or approximately 0.1 microns or less.

In an embodiment, the first optical waveguide 112 may be considered as being embedded in the first dielectric layer 110. However, it is to be appreciated that a surface of the first optical waveguide 112 (e.g., the bottom surface in FIG. 1A) may be substantially coplanar with a bottom surface of the first dielectric layer 110 (e.g., the bottom surface along the bonding interface 105 in FIG. 1A). Similarly, the second optical waveguide 122 may be considered as being embedded in the second dielectric layer 120 with a surface (e.g., the top surface in FIG. 1A) being substantially coplanar with a surface of the second dielectric layer 120 (e.g., the top surface along the bonding interface 105 in FIG. 1A).

In an embodiment, the device 100 may also comprise electrical interconnects at the bonding interface 105. For example, first interconnects 113 may directly contact second interconnects 123. That is, a direct metal-to-metal connection may be made between the first substrate and the second substrate. The first interconnects 113 may be coupled to a trace 114 embedded in the first dielectric layer 110, and the second interconnects 123 may be coupled to a trace 124 embedded in the second dielectric layer 120.

Referring now to FIG. 1B, a cross-sectional illustration of a portion of a device 100 is shown, in accordance with an additional embodiment. The device 100 in FIG. 1B may be similar to the device 100 in FIG. 1A, with the exception of the metal-to-metal bond of the interconnects. For example, the interconnects between the first substrate and the second substrate may further include first pads 116 on the first interconnects 113 and second pads 126 on the second interconnects 123. The use of pads may be beneficial for increasing the area of the metal-to-metal bond. This may allow for greater tolerance for misalignment during the hybrid bonding process.

Referring now to FIG. 1C, a plan view illustration of the first optical waveguide 112 and the second optical waveguide 122 is shown, in accordance with an embodiment. As shown, the first optical waveguide 112 and/or the second optical waveguide 122 may have non-uniform widths. For example, the first optical waveguide 112 may have a first portion 106 with a uniform width, a second portion 107 that is tapered, a third portion 108 with a uniform width, and a fourth portion 109 with another tapered width. The second optical waveguide 122 may have a first portion 127 with a uniform width and a second portion 128 with a tapered width.

As shown, the first optical waveguide 112 and the second optical waveguide 122 may partially overlap each other. For example, the third portion 108 and the fourth portion 109 of the first optical waveguide 112 may overlap the first portion 127 and the second portion 128 of the second optical waveguide 122. The overlapping tapered portions (e.g., the fourth portion 109 of the first optical waveguide 112 and the second portion 128 of the second optical waveguide 122) may allow for improved tolerances to misalignment. In some embodiments, the overlapping tapered portions of the first optical waveguide 112 and the second optical waveguide 122 may form a structure suitable for vertical adiabatic coupling. While a particular taper structure is shown for the first optical waveguide 112 and the second optical waveguide 122, it is to be appreciated that the design of the vertical adiabatic coupler may allow for any suitable dimensions, tapers, and/or overlaps in order to provide an optimized power transfer of the optical signal between the first optical waveguide 112 and the second optical waveguide 122.

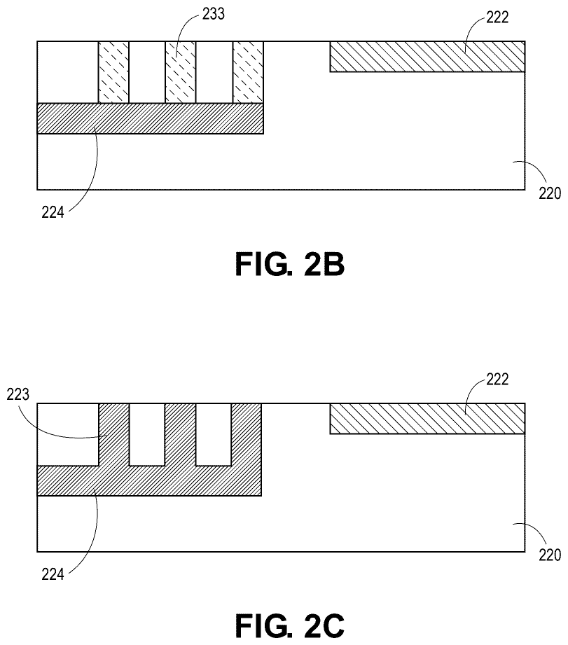

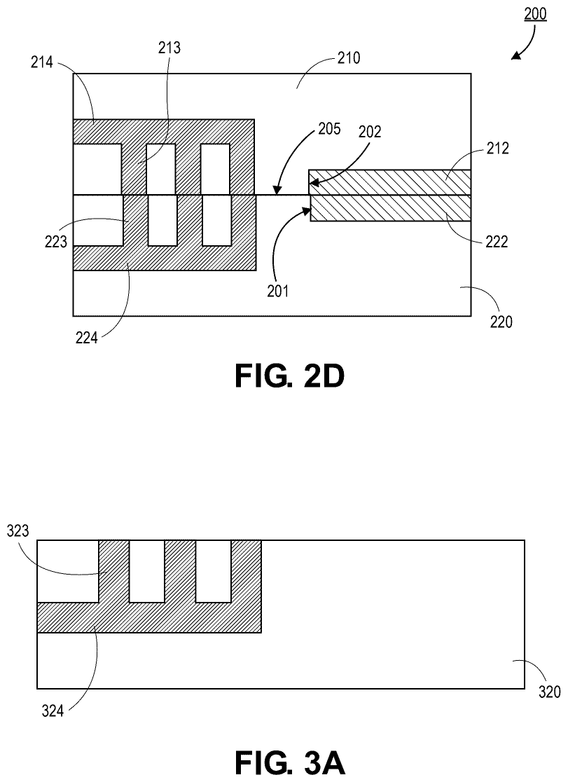

Referring now to FIG. 2A-2D, a series of cross-sectional illustrations depicting a process for forming a device 200 with a hybrid bonded interface that comprises electrical interconnects and optical interconnects is shown, in accordance with an embodiment.

Referring now to FIG. 2A, a cross-sectional illustration of a portion of a first substrate is shown, in accordance with an embodiment. In an embodiment, the first substrate may comprise a dielectric layer 220. The dielectric layer 220 may comprise a dielectric material suitable for hybrid bonding, such as silicon dioxide, glass, polyimide, or the like. In an embodiment, the dielectric layer 220 may be provided over any type of layer, such as a semiconductor die, an interposer (e.g., a silicon interposer or substrate, a glass interposer or substrate, etc.), and/or the like. In some embodiments, the hybrid bonding that is provided with the dielectric layer 220 may include an organic-to-organic dielectric bonding interface, an organic-to-inorganic dielectric bonding interface, and/or an inorganic-to-inorganic dielectric bonding interface.

In an embodiment, an electrically conductive trace 224 may be provided within the dielectric layer 220. While a single trace 224 is shown in FIG. 2A, it is to be appreciated that any number of electrical traces and/or other electrical routing may be embedded and/or partially embedded within the dielectric layer 220. As shown, a plurality of openings 232 may be provide into a surface of the dielectric layer 220. One or more of the openings 232 may be positioned over the trace 224, so that a portion of the trace 224 is exposed. In an embodiment, an additional opening 231 may be provided into the surface of the dielectric layer 220. The openings 232 and 231 may be formed with etching processes. For example, a patterned resist layer (not shown) may be provided over the dielectric layer 220, and the openings 232 and 231 are transferred into the dielectric layer 220 through the pattern in the resist layer.

In the illustrated embodiment, a depth of the openings 232 is different than a depth of the opening 231. This may be enabled through the use of multiple etching processes. For example, the openings 232 may be formed with an etching process that has a longer duration than the etching process used to form the opening 231. While the openings 231 and 232 are shown as have substantially vertical sidewalls, embodiments are not limited to such configurations. For example, sidewalls of the openings 231 and 232 may be tapered, curved, and/or the like, depending on the etching process used to form the openings 231 and 232.

Referring now to FIG. 2B, a cross-sectional illustration of the dielectric layer 220 after an optical waveguide 222 is formed in the opening 231. In an embodiment, the opening 231 may be filled with a dielectric material that has a refractive index that is greater than a refractive index of the dielectric layer 220. For example, the optical waveguide 222 may comprise a silicon nitride, a silicon oxynitride, a doped silicon dioxide, a silicon carbon nitride, a pre-polymer or a polymer (e.g. polyimide), or the like. The optical waveguide 222 may be deposited with a physical deposition process, a chemical deposition process, and/or the like.

In an embodiment, the openings 232 may be filled with a mask layer 233. The mask layer 233 may fill the openings 232 in order to prevent deposition of the dielectric material of the optical waveguide 222 into the openings 232. In an embodiment, the top surface may be planarized (e.g., with a chemical mechanical polishing (CMP) process or the like) in order to make a top surface of the optical waveguide 222 substantially coplanar with a top surface of the dielectric layer 220.

Referring now to FIG. 2C, a cross-sectional illustration of the dielectric layer 220 after interconnects 223 are formed over the trace 224 is shown, in accordance with an embodiment. In an embodiment, the mask layer 233 may be removed to clear the openings 232. Thereafter, a plating process or the like may be used in order to form the interconnects 223 within the openings 232. A polishing process may be used to set a surface profile of the top surface of the interconnects 223 relative to the top surface of the dielectric layer 220. As shown in FIG. 2C, the top surface of the interconnects 223 are substantially coplanar with the top surface of the dielectric layer 220. Though, in other embodiments, the top surface of the interconnects 223 may be slightly recessed from a top surface of the dielectric layer 220. Such a recessed profile for the interconnects 223 may be beneficial for the subsequent hybrid bonding process in some embodiments.

Referring now to FIG. 2D, a cross-sectional illustration of a portion of a device 200 after hybrid bonding is shown, in accordance with an embodiment. In an embodiment, the hybrid bonding may include bonding an opposing dielectric layer 210 to the dielectric layer 220 at a bonding interface 205. As shown, interconnects 213 of the upper dielectric layer 210 directly contact the interconnects 223 of the lower dielectric layer 220. The upper interconnects 213 may be electrically coupled to a trace 214 embedded in the upper dielectric layer 210. As such, the trace 214 may be electrically coupled to the trace 224 through the interconnects 213 and 223. That is, there may not be a solder or any other intervening electrically conductive structure between the interconnects 213 and 223.

Similarly, the optical waveguide 222 may be directly bonded to the optical waveguide 212 that is embedded in the upper dielectric layer 210. As such, the two optical waveguides 212 and 222 may be optically coupled together in order to allow for optical coupling between a substrate over the dielectric layer 210 and a substrate under the dielectric layer 220. More generally, the device 200 may include a hybrid bonding interface 205 that comprises electrical interconnects for electrical coupling and optical interconnects for optical coupling.

As shown in FIG. 2D, there may be some degree of offset or misalignment between the optical and/or electrical interconnects on either side of the hybrid bonding interface 205. For example, an edge 201 of the optical waveguide 222 may be offset from an edge 202 of the optical waveguide 212. Such an offset may be up to approximately 1.0 microns, up to approximately 0.5 microns, or up to approximately 0.1 microns. As such, the misalignment may be within an acceptable range in order to allow for highly efficient power transfer of optical signals between the optical waveguide 222 and the optical waveguide 212. Similarly, the interconnects 213 and 223 may have a minimal offset as well.

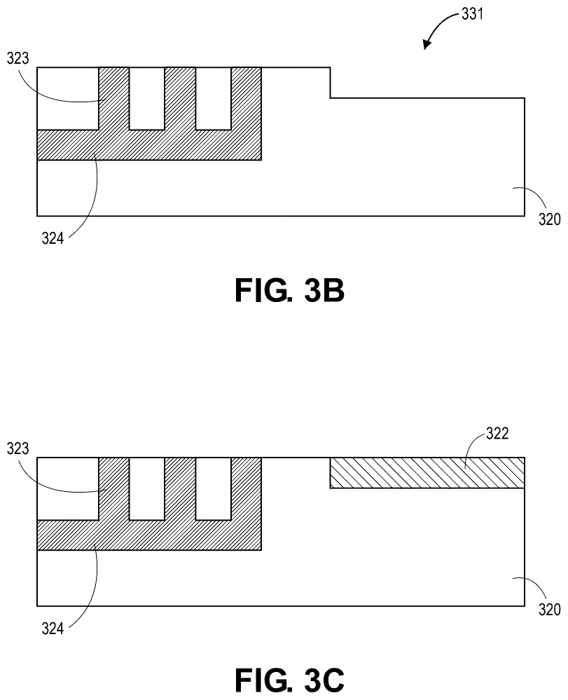

Referring now to FIG. 3A-3C, a series of cross-sectional illustrations that depict an alternative process for forming embedded optical waveguides within a dielectric layer is shown, in accordance with an additional embodiment.

Referring now to FIG. 3A, a cross-sectional illustration of a dielectric layer 320 is shown, in accordance with an embodiment. The dielectric layer 320 may be similar to the dielectric layer 220 described above. For example, the dielectric layer 320 may have a relatively low refractive index, and the dielectric layer 320 may be provided as a top layer of a substrate (e.g., a die, an interposer, or the like).

As shown, a trace 324 may be embedded within the dielectric layer 320, and one or more interconnects 323 may be formed between the trace 324 and a top surface of the dielectric layer 320. The interconnects 323 may be formed with any suitable patterning and deposition process.

Referring now to FIG. 3B, a cross-sectional illustration of the dielectric layer 320 after an opening 331 is formed into the top surface of the dielectric layer 320. In an embodiment, the opening 331 may be formed with an etching process or the like. In an embodiment, the etching process may include forming a patterned mask over the dielectric layer 320 and transferring the pattern of the mask into the top surface of the dielectric layer 320 with an etching process.

Referring now to FIG. 3C, a cross-sectional illustration of the dielectric layer 320 after the optical waveguide 322 is formed in the opening 331 is shown, in accordance with an embodiment. In an embodiment, the optical waveguide 322 may be similar to the optical waveguide 222 described above. For example, the optical waveguide 322 may comprise a dielectric material with a refractive index that is greater than a refractive index of the dielectric layer 320. For example, the optical waveguide may comprise a silicon nitride, a silicon oxynitride, a doped silicon dioxide, a pre-polymer or a polymer (e.g. polyimide) or the like.

After the electrical interconnects 323 and the optical waveguide 322 are formed, the dielectric layer 320 may be hybrid bonded to an opposing dielectric layer (not shown) with similar electrical interconnects and an optical waveguide to form a structure similar to the device 200 shown in FIG. 2D.

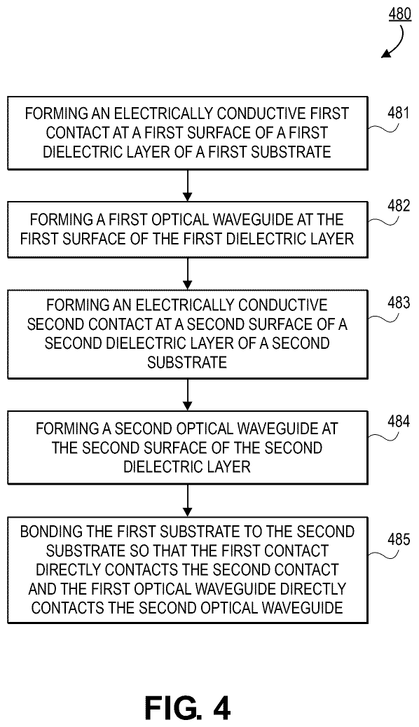

Referring now to FIG. 4, a flow diagram that describes a process 480 for forming a hybrid bonded device with electrical coupling and optical coupling is shown, in accordance with an embodiment. In an embodiment, the process 480 may begin with operation 481, which comprises forming an electrically conductive first contact at a first surface of a first dielectric layer of a first substrate. In an embodiment, the first dielectric layer may comprise a dielectric material with a relatively low refractive index.

In an embodiment, the process 480 may continue with operation 482, which comprises forming a first optical waveguide at the first surface of the first dielectric layer. In an embodiment, the first optical waveguide may comprise a dielectric material with a refractive index that is higher than the refractive index of the first dielectric layer. In an embodiment, the first contact and the first optical waveguide may be embedded in the first dielectric layer so that the top surfaces of the first contact and the first optical waveguide are substantially coplanar and/or slightly recessed from the first surface of the first dielectric layer.

In an embodiment, the process 480 may continue with operation 483, which comprises forming an electrically conductive second contact at a second surface of a second dielectric layer of a second substrate. In an embodiment, the second dielectric layer may comprise a dielectric material with a relatively low refractive index.

In an embodiment, the process 480 may continue with operation 484, which comprises forming a second optical waveguide at the second surface of the second dielectric layer. In an embodiment, the second optical waveguide may comprise a dielectric material with a refractive index that is higher than the refractive index of the second dielectric layer. In an embodiment, the second contact and the second optical waveguide may be embedded in the second dielectric layer so that the top surfaces of the second contact and the second optical waveguide are substantially coplanar and/or slightly recessed from the second surface of the second dielectric layer.

In an embodiment, the process 480 may continue with operation 485, which comprises bonding the first substrate to the second substrate. In an embodiment, the bonding process is a hybrid bonding process. This allows for the first contact to directly contact the second contact and allows for the first optical waveguide to directly contact the second optical waveguide. Accordingly, the resulting device may comprise a hybrid bonding interface with electrical coupling and optical coupling.

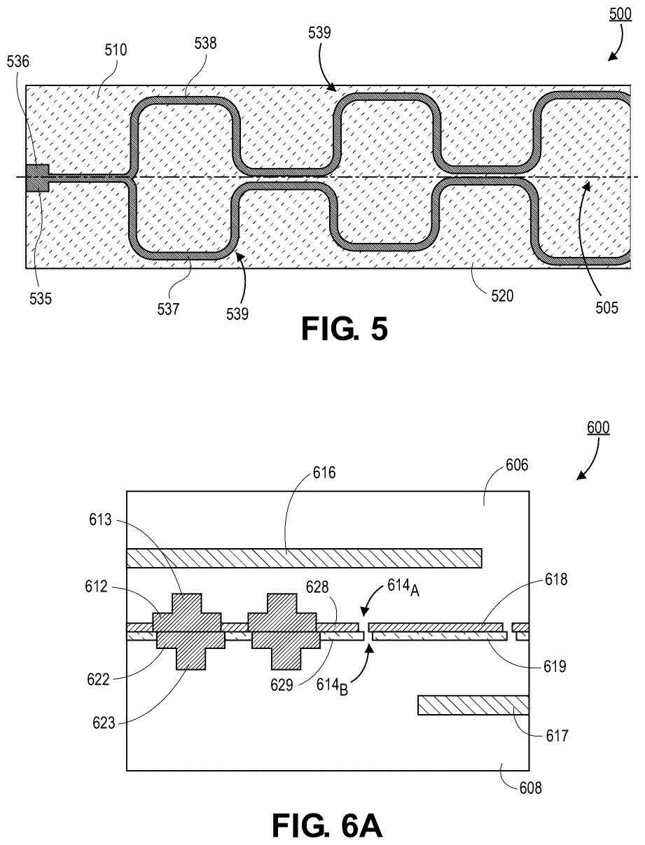

Referring now to FIG. 5, a cross-sectional illustration of a portion of a device 500 is shown, in accordance with an embodiment. In an embodiment, the device 500 may include a first dielectric layer 520 that is bonded to a second dielectric layer 510 (e.g., with a hybrid bonding process). In an embodiment, the first dielectric layer 520 and the second dielectric layer 510 may comprise embedded optical waveguide structures 537 and 538. In an embodiment, waveguide inputs 535 and 536 within each dielectric layer 520 and 510, respectively, may be directly contacting each other at the hybrid bonding interface 505.

In an embodiment, the optical waveguide structures 537 and 538 may each include horizontal and vertical portions. Additionally, corner regions 539 between horizontal and vertical portions may be curved. Such two dimensional paired optical waveguide structures may be used in order to form optical components used to modify optical signals within the device 500. For example, the optical waveguide structures 537 and 538 may be configured as an optical resonator, an optical filter, or the like.

In an embodiment, the two-dimensional optical waveguide structures 537 and 538 may be formed using patterning and deposition processes similar to the processes described with respect to FIG. 2A-2D and/or FIG. 3A-3C. For example, a trench with non-uniform depth may be formed into the surfaces of the dielectric layers 510 and 520. The curved corners regions 539 may be formed with grayscale lithography processes in some embodiments. A conformal deposition process may be used to deposit the optical waveguide structures 537 and 538. Thereafter, the remainder of the trenches may be filled with a dielectric material and planarized to provide a suitable planar surface for subsequent hybrid bonding.

In the illustrated embodiments, the optical waveguide structures 537 and 538 are shown as having the same shading. However, it is to be appreciated that the optical waveguide structures 537 and 538 may comprise different dielectric materials to form a heterogeneous optical component.

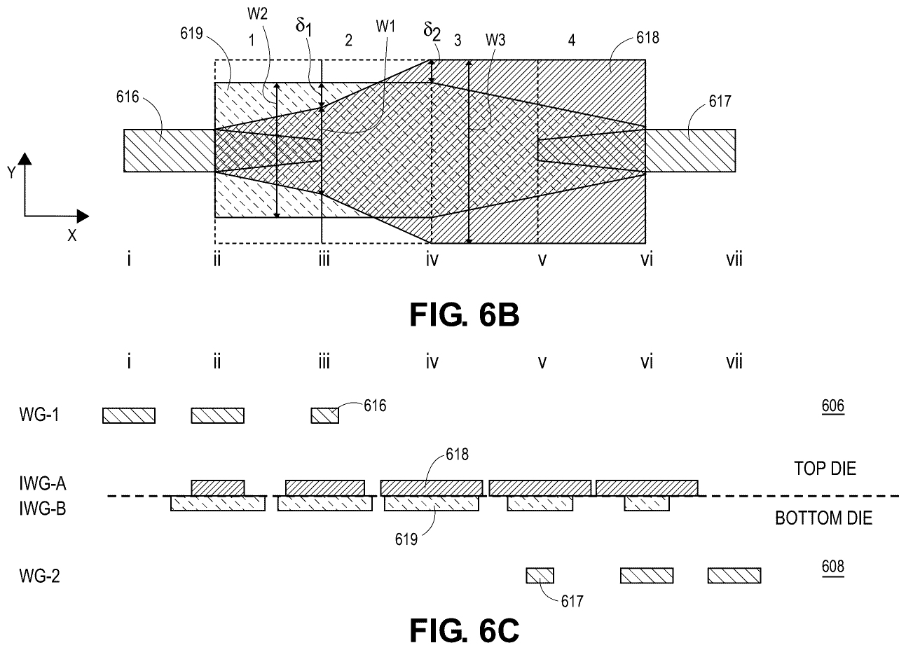

Referring now to FIG. 6A-6C, a series of illustrations that shown a device 600 with an optical coupler that is formed at the hybrid bonding interface is shown, in accordance with an embodiment. In such an embodiment, the optical coupler allows for the vertical propagation of optical signals between substrates without the need for vertically oriented optical waveguides. As such, the optical routing may be simplified.

This can reduce costs of fabrication as well as providing more space for additional optical IO lanes.

Referring now to FIG. 6A, a cross-sectional illustration of a device 600 is shown, in accordance with an embodiment. As shown, a first substrate 608 is hybrid bonded to a second substrate 606. In an embodiment, a first dielectric layer 629 is provided over the first substrate 608 and a second dielectric layer 628 is provided over the second substrate 606. In some embodiments, gaps 614_{A} and 614_{B} may be provided in the dielectric layers 628 and 629 in order to define interface optical waveguides 618 and 619 at the hybrid bonding interface between the first substrate 608 and the second substrate 606. In some embodiments, the gaps 614_{A} and/or 614_{B} may be filled with a material with a lower refractive index than the first substrate 608 and/or the second substrate 606. The gaps 614_{A} and/or 614_{B} may also comprise air gaps. In yet another embodiment, the gaps 614_{A} and/or 614_{B} may be filled with the same material as the first substrate 608 and/or the second substrate 606. Pads 612 and 622 with vias 613 and 623, respectively, may also be directly bonded to each other at the hybrid bonding interface.

In an embodiment, the interface optical waveguide formed by optical waveguides 618 and 619 may be optically coupled to optical waveguide 617 in the first substrate 608 and to optical waveguide 616 in the second substrate 606. In some embodiments, the optical waveguide 618 and the optical waveguide 619 are bonded together so that there may be no discernable boundary between the two optical waveguides 618 and 619. That is, the bonded structure of the optical waveguide 618 and the optical waveguide 619 may be considered as being a single interface optical waveguide in some embodiments. In this way, an optical signal propagated along the optical waveguide 616 in the second substrate 606 can be transmitted to the optical waveguide 617 in the first substrate 608 through the interface optical waveguide formed by the bonding of the optical waveguide 618 to the optical waveguide 619. Similarly, optical signals propagated along the optical waveguide 617 may be transmitted to the optical waveguide 616 through the interface optical waveguide formed by the bonding of the optical waveguide 618 to the optical waveguide 619. In various embodiments, one or more of the optical waveguide 616, the optical waveguide 617, the optical waveguide 618, and/or the optical waveguide 619 may comprise the same high refractive index material and/or different high refractive index materials. In an embodiment, the first substrate 608 and/or the second substrate 606 may comprises the same or different low refractive index materials. More generally, the material (or materials) for the first substrate 608 and/or the second substrate 606 may have lower refractive indices than the material (or materials) for the optical waveguides 616-619.

Referring now to FIG. 6B, a plan view illustration of the structure of the vertical optical coupler is shown, in accordance with an embodiment. FIG. 6C is a series of cross-sectional slices of the vertical optical coupler along lines i-vii. As shown, the vertical optical coupler may have a rib waveguide structure with four regions 1-4. In an embodiment, region 1 couples an optical signal from the optical waveguide 616 to the interface optical waveguide formed by optical waveguides 618 and 619. Region 2 may expand the mode with the interface optical waveguide of optical waveguides 618 and 619. In an embodiment, region 3 may realign the mode. Region 3 may also be used as a multi-mode to single mode converter in some embodiments. In an embodiment, region 4 couples the optical signal from the interface optical waveguides 618 and 619 to the optical waveguide 617.

In an embodiment, the tapers of the interface optical waveguide formed by optical waveguides 618 and 619 may be chosen such that δ₁ is equal to δ₂. In some embodiments, the tapers are patterned such that W₁+2 δ=W₂ and W₂+2 δ=W₃. With these dimensional constraints, the structure is alignment-invariant for misalignment M≤δ along the y-axis. For example, to allow for 500 nm of misalignment, δ≥500 nm.

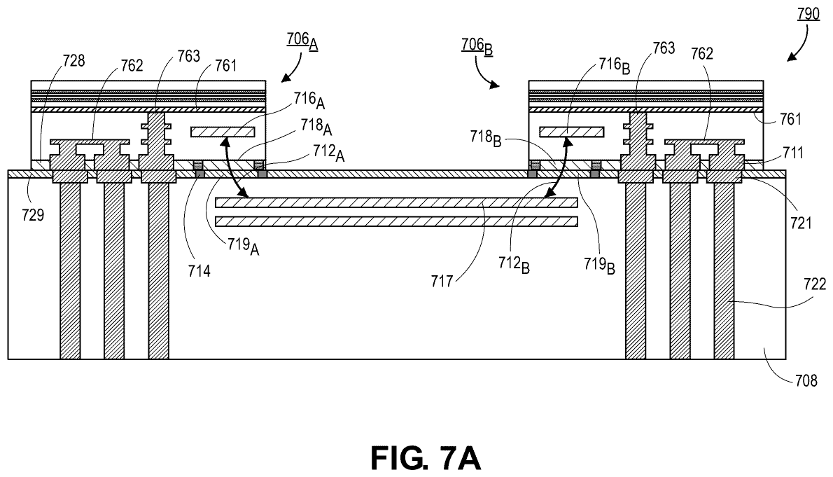

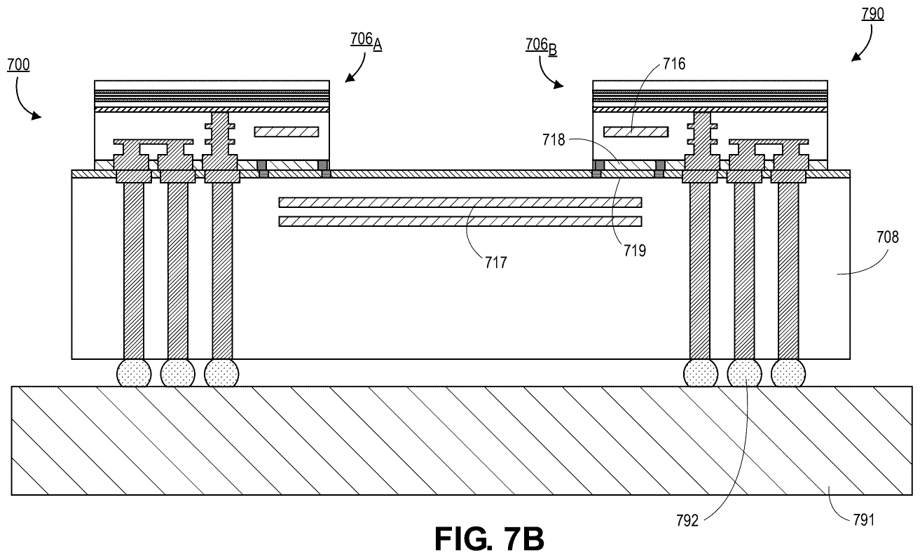

Referring now to FIG. 7A, a cross-sectional illustration of a device 700 is shown, in accordance with an embodiment. As shown, the device 700 may comprise one or more substrate 706 (e.g., 706_{A} and 706_{B}) that are hybrid bonded to an additional substrate 708. In an embodiment, the substrates 706_{A} and 706_{B} may be dies, such as monolithic and/or quasi-monolithic chips. For example, the substrates 706_{A} and 706_{B} may comprise an xPU, a memory device, a switch, a controller, or the like. The substrate 708 may comprise an interposer, such as an electro-optical interposer. For example, the substrate 708 may be monolithic or disaggregated. The substrate 708 may be a wafer-level substrate, a panel level substrate, a single reticle die size, a multi-reticle die size, or the like.

In an embodiment, the substrates 706_{A} and 706_{B} may comprise a device layer 761, which comprises transistor devices and/or the like. In an embodiment, electrical interconnects (e.g., vias 763, traces 762, pads 711, and/or the like) may be electrically couple the device layer 761 to electrical pads 721 and/or vias 722 in the substrate 708. For example, pads 711 may be directly bonded to pads 721 in a hybrid bonding process. Dielectric optical waveguides 718_{A} and 718_{B} may be provided over surfaces of the substrates 706_{A} and 706_{B} within dielectric layer 728 in order to provide dielectric-to-dielectric bonding interfaces with dielectric optical waveguides 719_{A} and 719_{B} that are within a dielectric layer 729 of the substrate 708. In an embodiment, gaps 714 may be provided along the dielectric layers 728 to define the optical waveguides 718_{A} and 718_{B} on the substrates 706_{A} and 706_{B} and in dielectric layer 729 in order to define optical waveguides 719_{A} and 719_{B} on the substrate 708. The optical waveguides 718_{A} and 719_{A} may be directly bonded to each other at the hybrid bonding interface, and the optical waveguides 718_{B} and 719_{B} may be directly bonded to each other at the hybrid bonding interface.

In an embodiment, an optical waveguide 716_{A} may be embedded in the substrate 706_{A}, and an optical waveguide 716_{B} may be embedded in the substrate 706_{B}. One or more optical waveguides 717 may be embedded in the substrate 708 as well. In an embodiment, optical waveguide 716_{A} may be optically coupled (as indicated by line 712_{A}) to one of the optical waveguides 717 by the interface optical waveguides 718_{A} and 719_{A} which may function as a vertical optical coupling structure similar to the one described with respect to FIG. 6A-6C. For example, the gaps 714 (e.g., air gaps, low refractive index dielectric material, or the like) may be used to define the optical waveguides 718_{A} and 719_{A} as well as the optical waveguides 718_{B} and 719_{B}. In an embodiment, the bonded optical waveguides 718_{A} and 719_{A} may be considered as a single interface optical waveguide, and the bonded optical waveguides 718_{B} and 719_{B} may be considered as a single interface optical waveguide. Similarly, optical waveguide 716_{B} may be optically coupled (as indicated by line 712_{B}) to one of the optical waveguides 717 through a vertical optical coupling structure formed by interface optical waveguides 718_{B} and 719_{B}. In this way the substrate 706_{A} is optically coupled to the substrate 706_{B} through the substrate 708. Accordingly, high data bandwidths with efficient power consumption may be enabled between the substrates 706_{A} and 706_{B}.

Referring now to FIG. 7B, a cross-sectional illustration of an optoelectronic system 790 is shown, in accordance with an embodiment. In an embodiment, the optoelectronic system 790 may comprise a board 791, such as a printed circuit board (PCB), a motherboard, or the like. In an embodiment, an optoelectronic device 700 is coupled to the board 791 by interconnects 792. The interconnects 792 may be any suitable second level interconnect (SLI), such as solder bumps, sockets, or the like.

In an embodiment, the optoelectronic device 700 may be similar to any of the devices described in greater detail herein. For example, the optoelectronic device 700 may comprise a pair of substrates 706_{A} and 706_{B} that are hybrid bonded to an interposer substrate 708. In an embodiment, the substrates 706_{A} and 706_{B} may include optical waveguides 716 that are optically coupled to an optical waveguide 717 in the substrate 708 by interface optical waveguides 718 and 719. As such, the substrate 706_{A} may be optically coupled to the substrate 706_{B} through the substrate 708. More generally, the device 700 may comprise a 2.5D or 3D structure with hybrid bonded interfaces that comprises metal-to-metal interconnects for electrical coupling between substrates and dielectric-to-dielectric optical waveguide interconnects for optical coupling between substrates.

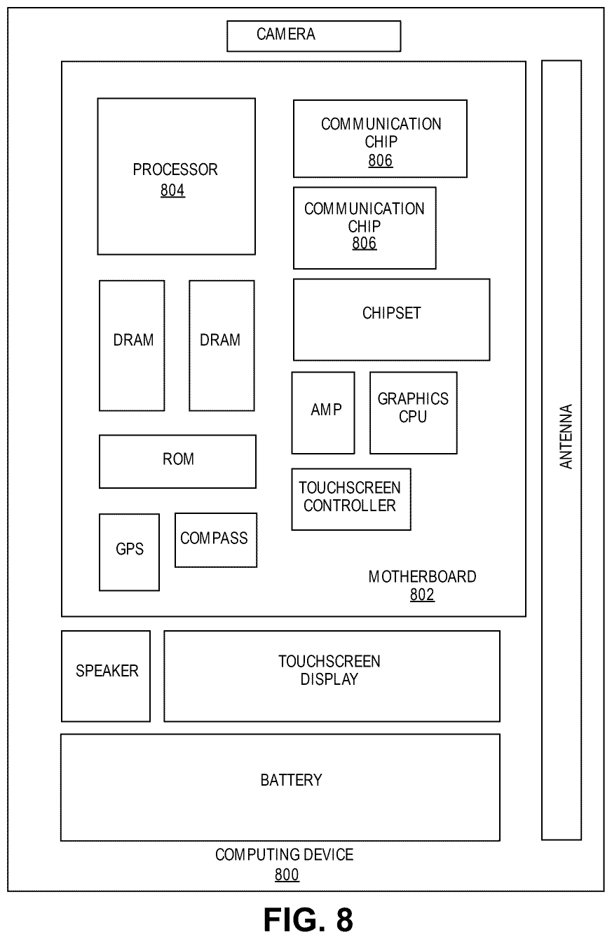

FIG. 8 illustrates a computing device 800 in accordance with one implementation of the disclosure. The computing device 800 houses a board 802. The board 802 may include a number of components, including but not limited to a processor 804 and at least one communication chip 806. The processor 804 is physically and electrically coupled to the board 802. In some implementations the at least one communication chip 806 is also physically and electrically coupled to the board 802. In further implementations, the communication chip 806 is part of the processor 804.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 806 enables wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 806 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 800 may include a plurality of communication chips 806. For instance, a first communication chip 806 may be dedicated to shorter range wireless communications such as Wi-Fi and Bluetooth and a second communication chip 806 may be dedicated to longer range wireless communications such as GPS, EDGE, GPRS, CDMA, WiMAX, LTE, Ev-DO, and others.

The processor 804 of the computing device 800 includes an integrated circuit die packaged within the processor 804. In some implementations of the disclosure, the integrated circuit die of the processor may be part of an optoelectronic system that includes extended hybrid bonding with a photonic interface, in accordance with embodiments described herein. The term “processor” may refer to any device or portion of a device that processes electronic data from registers and/or memory to transform that electronic data into other electronic data that may be stored in registers and/or memory.

The communication chip 806 also includes an integrated circuit die packaged within the communication chip 806. In accordance with another implementation of the disclosure, the integrated circuit die of the communication chip may be part of an optoelectronic system that includes extended hybrid bonding with a photonic interface, in accordance with embodiments described herein.

In an embodiment, the computing device 800 may be part of any apparatus. For example, the computing device may be part of a personal computer, a server, a mobile device, a tablet, an automobile, or the like. That is, the computing device 800 is not limited to being used for any particular type of system, and the computing device 800 may be included in any apparatus that may benefit from computing functionality.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

Example 1: an apparatus, comprising: a first layer comprising a first dielectric material; a second layer comprising a second dielectric material embedded within the first layer, wherein the second dielectric material has a higher index of refraction than the first dielectric material; a first contact that is electrically conductive embedded in the first layer; a third layer comprising a third dielectric material; a fourth layer comprising a fourth dielectric material embedded within the third layer, wherein the fourth dielectric material has a higher index of refraction than the third dielectric material; and a second contact that is electrically conductive embedded in the third layer, wherein the first layer directly contacts the third layer, and wherein the second layer directly contacts the fourth layer, and wherein the first contact directly contacts the second contact.

Example 2: the apparatus of Example 1, wherein the second layer and the fourth layer are optical waveguides.

Example 3: the apparatus of Example 1 or Example 2, wherein the second dielectric material and the fourth dielectric material are different.

Example 4: the apparatus of Examples 1-3, wherein the second dielectric material and the fourth dielectric material are the same.

Example 5: the apparatus of Examples 1-4, wherein the second dielectric material and the fourth dielectric material comprise one or more of a composition comprising silicon and oxygen with a dopant, a composition comprising silicon and nitrogen, a composition comprising silicon, carbon and nitrogen, a composition comprising silicon, oxygen, and nitrogen, or a composition comprising a polymer material.

Example 6: the apparatus of Examples 1-5, wherein the second layer and the fourth layer comprise non-uniform widths, and wherein a first tapered region of the second layer overlaps a second tapered region of the fourth layer.

Example 7: the apparatus of Example 6, wherein the second layer and the fourth layer are configured to enable adiabatic optical coupling.

Example 8: the apparatus of Examples 1-7, wherein an edge of the first contact is offset from an edge of the second contact by 1.0 micron or less.

Example 9: the apparatus of Examples 1-8, wherein the first layer is part of a first substrate, and the third layer is part of a second substrate, wherein the first substrate is hybrid bonded to the second substrate.

Example 10: the apparatus of Example 9, wherein the first substrate is a die with a transistor device, and wherein the second substrate is an interposer.

Example 11: an apparatus, comprising a first substrate, comprising a first optical waveguide embedded in the first substrate; a second substrate, comprising a second optical waveguide embedded in the second substrate; and a third optical waveguide embedded in the first substrate and the second substrate, wherein the third optical waveguide overlaps a portion of the first optical waveguide and a portion of the second optical waveguide; and wherein the first substrate is bonded to the second substrate, and wherein an interface between the first substrate and the second substrate is between a top surface of the third optical waveguide and a bottom surface of the third optical waveguide.

Example 12: the apparatus of Example 11, wherein the first optical waveguide is configured to be optically coupled to the third optical waveguide through the second optical waveguide.

Example 13: the apparatus of Example 11 or Example 12, wherein the second optical waveguide has a first tapered region within the first substrate and a second tapered region within the second substrate.

Example 14: the apparatus of Example 13, wherein the first optical waveguide overlaps the first tapered region, and wherein the second optical waveguide overlaps the second tapered region.

Example 15: the apparatus of Examples 11-14, further comprising: a first pad in the first substrate; and a second pad in the second substrate, wherein the first pad directly contacts the second pad.

Example 16: the apparatus of Examples 11-15, wherein the first optical waveguide has a first tapered end that overlaps the third optical waveguide, and wherein the second optical waveguide has a second tapered end that overlaps the third optical waveguide.

Example 17: an apparatus, comprising: a first substrate, comprising: a first optical input at a first surface of the first substrate; and a first optical waveguide coupled to the first optical input, wherein the first optical waveguide extends horizontally and vertically within the first substrate; and a second substrate that is bonded to the first substrate, wherein the second substrate comprises: a second optical input at a second surface of the second substrate, wherein the second optical input directly contacts the first optical input; and a second optical waveguide coupled to the second optical input, wherein the second optical waveguide extends horizontally and vertically within the second substrate.

Example 18: the apparatus of Example 17, wherein the first optical waveguide and the second optical waveguide are configured to form an optical filter or an optical resonator.

Example 19: the apparatus of Example 17 or Example 18, wherein a corner of the first optical waveguide between a horizontal portion and a vertical portion is curved.

Example 20: the apparatus of Examples 17-19, further comprising: a first contact in the first substrate; and a second contact in the second substrate, wherein the first contact directly contacts the second contact.

What is claimed is:

1. An apparatus, comprising:
a first layer comprising a first dielectric material;
a second layer comprising a second dielectric material embedded within the first layer, wherein the second dielectric material has a higher index of refraction than the first dielectric material;
a first contact that is electrically conductive embedded in the first layer;
a third layer comprising a third dielectric material;
a fourth layer comprising a fourth dielectric material embedded within the third layer, wherein the fourth dielectric material has a higher index of refraction than the third dielectric material; and
a second contact that is electrically conductive embedded in the third layer, wherein the first layer directly contacts the third layer, and wherein the second layer directly contacts the fourth layer, and wherein the first contact directly contacts the second contact.

2. The apparatus of claim 1, wherein the second layer and the fourth layer are optical waveguides.

3. The apparatus of claim 1, wherein the second dielectric material and the fourth dielectric material are different.

4. The apparatus of claim 1, wherein the second dielectric material and the fourth dielectric material are the same.

5. The apparatus of claim 1, wherein the second dielectric material and the fourth dielectric material comprise one or more of a composition comprising silicon and oxygen with a dopant, a composition comprising silicon and nitrogen, a composition comprising silicon, carbon and nitrogen, a composition comprising silicon, oxygen, and nitrogen, or a composition comprising a polymer material.

6. The apparatus of claim 1, wherein the second layer and the fourth layer comprise non-uniform widths, and wherein a first tapered region of the second layer overlaps a second tapered region of the fourth layer.

7. The apparatus of claim 6, wherein the second layer and the fourth layer are configured to enable adiabatic optical coupling.

8. The apparatus of claim 1, wherein an edge of the first contact is offset from an edge of the second contact by 1.0 micron or less.

9. The apparatus of claim 1, wherein the first layer is part of a first substrate, and the third layer is part of a second substrate, wherein the first substrate is hybrid bonded to the second substrate.

10. The apparatus of claim 9, wherein the first substrate is a die with a transistor device, and wherein the second substrate is an interposer.

11. An apparatus, comprising
a first substrate, comprising a first optical waveguide embedded in the first substrate;
a second substrate, comprising a second optical waveguide embedded in the second substrate; and
a third optical waveguide embedded in the first substrate and the second substrate, wherein the third optical waveguide overlaps a portion of the first optical waveguide and a portion of the second optical waveguide; and
wherein the first substrate is bonded to the second substrate, and wherein an interface between the first substrate and the second substrate is between a top surface of the third optical waveguide and a bottom surface of the third optical waveguide.

12. The apparatus of claim 11, wherein the first optical waveguide is configured to be optically coupled to the third optical waveguide through the second optical waveguide.

13. The apparatus of claim 11, wherein the second optical waveguide has a first tapered region within the first substrate and a second tapered region within the second substrate.

14. The apparatus of claim 13, wherein the first optical waveguide overlaps the first tapered region, and wherein the second optical waveguide overlaps the second tapered region.

15. The apparatus of claim 11, further comprising:
a first pad in the first substrate; and
a second pad in the second substrate, wherein the first pad directly contacts the second pad.

16. The apparatus of claim 11, wherein the first optical waveguide has a first tapered end that overlaps the third optical waveguide, and wherein the second optical waveguide has a second tapered end that overlaps the third optical waveguide.

17. An apparatus, comprising:
a first substrate, comprising:
a first optical input at a first surface of the first substrate; and
a first optical waveguide coupled to the first optical input, wherein the first optical waveguide extends horizontally and vertically within the first substrate; and
a second substrate that is bonded to the first substrate, wherein the second substrate comprises:
a second optical input at a second surface of the second substrate, wherein the second optical input directly contacts the first optical input; and
a second optical waveguide coupled to the second optical input, wherein the second optical waveguide extends horizontally and vertically within the second substrate.

18. The apparatus of claim 17, wherein the first optical waveguide and the second optical waveguide are configured to form an optical filter or an optical resonator.

19. The apparatus of claim 17, wherein a corner of the first optical waveguide between a horizontal portion and a vertical portion is curved.

20. The apparatus of claim 17, further comprising:
a first contact in the first substrate; and
a second contact in the second substrate, wherein the first contact directly contacts the second contact.
